(19) United States
(12) Patent Application Publication
(10) Pub. No.: US 2019/0013301 A1
(43) Pub. Date: Jan. 10, 2019

(54) STACKED DIES WITH PASSIVE COMPONENTS WITHIN FACING RECESSES

(71) Applicant: Intel Corporation, Santa Clara, CA (US)

(72) Inventors: Bok Eng CHEAH, Gelugor (MY); Jackson Chung Peng KONG, Penang (MY); Kooi Chi OOI, Bukit Gambir (MY)

(21) Appl. No.: 15/996,093

(22) Filed: Jun. 1, 2018

(30) Foreign Application Priority Data
Jul. 4, 2017 (MY) PI 2017702438

(51) Int. Cl. H01L 25/16; H01L 25/065; H01L 23/48; H01L 23/498; H01L 23/00; H01L 25/00; H01L 21/768; H01L 23/31

(52) U.S. Cl. CPC H01L 25/16; H01L 2225/06565; H01L 23/481; H01L 23/49822; H01L 24/16; H01L 25/50; H01L 23/49816; H01L 21/76898; H01L 23/49838; H01L 23/3128; H01L 2225/06513; H01L 2225/06517; H01L 2224/16146; H01L 2225/06586; H01L 2924/19041; H01L 2924/19105; H01L 2924/19104; H01L 2224/16227; H01L 2224/17181; H01L 24/17; H01L 2225/06541; H01L 25/0657

(57) ABSTRACT

Embodiments herein may include apparatuses, systems, and processes related to stacked dies that include recesses into which passive components, such as decoupling capacitors, may be included. Embodiments may include a first die with a first side and a second side opposite the first side, a second die with a first side coupled to the second side of the first die, a recess in the first side of the second die, wherein a portion of a passive component is located within the recess of the first side of the second die, and wherein the passive component is coupled with the first die, the second die, or both. Other embodiments may be described and/or claimed.

### FIELD

Embodiments of the present disclosure generally relate to the field of package assemblies, and in particular, package assemblies having facing recesses to accommodate passive components.

### BACKGROUND

The background description provided herein is for the purpose of generally presenting the context of the disclosure. Unless otherwise indicated herein, the materials described in this section are not prior art to the claims in this application and are not admitted to be prior art by inclusion in this section.

As semiconductor packaging continues to drive towards increased density and increased functionality, the popularity of stacked-die architecture implementations will likely increase.

### BRIEF DESCRIPTION OF THE DRAWINGS

FIG. 1 illustrates an example of a vertically stacked die package assembly where the dies include one or more recesses, in accordance with embodiments.

FIG. 2 illustrates an example of a vertically stacked die package assembly where the dies include one or more recesses with through silicon vias (TSV) connected to other dies, in accordance with embodiments.

FIG. 3 illustrates an example of a vertically stacked die package assembly where the dies include one or more recesses with through silicon vias (TSV) connected to a substrate layer, in accordance with embodiments.

FIGS. 4A-4G illustrate an example of a vertically stacked die package assembly process where the dies include one or more recesses at various stages of a manufacturing process, in accordance with embodiments.

FIG. 5 illustrates an example flow diagram showing a process for manufacturing a stacked die package where the dies include one or more recesses that include passive components, in accordance with embodiments.

FIG. 6 schematically illustrates a computing device, in accordance with embodiments.

### DETAILED DESCRIPTION

Embodiments of the present disclosure generally relate to a semiconductor package including vertically stacked dies with one or more recesses on one or more lateral surfaces of the one or more stacked dies where various components may be located within recesses in the stacked dies. In embodiments, the recesses may be within the silicon portion in a die. In embodiments, the recesses may be through an active layer of the die. In embodiments, one or more passive components, for example, a decoupling capacitor, may be partially located within the silicon recess and may be electrically coupled to an active layer adjacent to the recess, or to an active layer of another die.

In embodiments, one or more decoupling capacitors may be used within vertically stacked dies of a package, and as a result may provide a more efficient, stable, and continuous power delivery solution for components within the vertically stacked dies. In addition, such implementation may alleviate the need to place decoupling capacitors on the package, which may result in reduced space for ball grid arrays (BGA) and/or additional substrate space proximate to where the vertically stacked dies may be placed on and/or coupled to a substrate.

Legacy implementations of power delivery solutions for a stacked die architecture, where capacitors are located outside of the stacked dies, are subject to inefficiencies due to an increased decoupling loop-inductance path. This increased decoupling loop-inductance path may result from the distance between the decoupling capacitors, located on a package substrate, and power loading, for example, transceiver power loading, within the stacked dies. Decoupling loop-inductance may be particularly evident for the upper-stacked dies farthest from the package substrate. For example, a die located farthest from the package substrate may have a large and undesirable loop-inductance from a die-side capacitor (DSC) or a land-side capacitor (LSC) attached on the package substrate. This makes the overall power delivery, for example, current drawn from capacitor components to the device power rail, inferior compared to the bottom die closest to the package substrate. Such decoupling loop-inductance path may impede continuous device performance scaling for example, through increased signal noise and/or jitter that limits the operating frequency or bandwidth of the device, and/or form-factor miniaturization, for example through large package foot-print required for DSCs and/or LSCs placement.

Legacy implementations to address power delivery challenges in packages with stacked dies include silicon metal-in-metal capacitor (MIMCap) and/or increased numbers of package decoupling capacitors (DSCs and/or LSCs). These legacy implementations, however, may increase production costs of silicon fabrication and/or packages, may result in trade-off device performance scaling, for example, from lower package input/output (I/O) density, and/or may hinder package/device miniaturizations.

By contrast, embodiments of packages with vertically stacked dies herein may include improved power delivery through shorter and/or more direct decoupling loop-inductance paths from decoupling capacitors disposed in the recesses of the dies, as compared to legacy implementations of DSCs/LSCs located at the package substrate level. As a result, these embodiments may enable increased device bandwidth and/or performance scaling through reduced signaling jitters.

As discussed above, a decoupling loop inductance path is one of the major factors in determining power integrity performance. In embodiments, a smaller and/or a shorter decoupling loop inductance path is desirable to accomplish optimum performance. The decoupling loop inductance may be directly proportional to the distance between the decoupling capacitor and a transceiver power loading and/or network and/or other components that may be on an active side of a die. Therefore, in embodiments, the effectiveness of a power delivery solution with stacked inter-die capacitors attached directly to a respective silicon active region (in between the stacked silicon layers) may provide significant advantages over legacy implementations, e.g., package land-side capacitors, package die-side capacitors and board edge capacitors for stacked die applications. In embodiments, the manufacturing process to fabricate the stacked dies package with the inter-die capacitor may use existing technologies such as, for example, surface mounting, wafer stacking or wafer level packaging processes.

In embodiments, such form-factor miniaturization may be realized through reduction of a package footprint required for package DSCs attachment, for example, DSC pads, and/or increased BGA I/O density through fully populated BGA connections on the land side of the package substrate. In embodiments, this may result through the elimination or reduction of LSCs.

In embodiments, there may be a reduction of silicon MIMCap requirements, which may include capacitance formed between metal layers within the silicon active layer, via an efficient noise decoupling solution. In embodiments, the decoupling capacitor located within the one or more recesses of the stacked dies may provide the capability to supply instantaneous power to at least one of the stacked dies to reduce power supply noise and/or jitter. As a result, there may be a reduction in production costs through a reduced silicon footprint and/or reduced fabrication cycle.

In the following detailed description, reference is made to the accompanying drawings that form a part hereof, wherein like numerals designate like parts throughout, and in which is shown by way of illustration embodiments in which the subject matter of the present disclosure may be practiced. It is to be understood that other embodiments may be utilized and structural or logical changes may be made without departing from the scope of the present disclosure. Therefore, the following detailed description is not to be taken in a limiting sense, and the scope of embodiments is defined by the appended claims and their equivalents.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B and C).

The description may use perspective-based descriptions such as top/bottom, in/out, over/under, and the like. Such descriptions are merely used to facilitate the discussion and are not intended to restrict the application of embodiments described herein to any particular orientation.

The description may use the phrases “in an embodiment,” or “in embodiments,” which may each refer to one or more of the same or different embodiments.

Furthermore, the terms “comprising,” “including,” “having,” and the like, as used with respect to embodiments of the present disclosure, are synonymous.

The term “coupled with,” along with its derivatives, may be used herein. “Coupled” may mean one or more of the following. “Coupled” may mean that two or more elements are in direct physical or electrical contact. However, “coupled” may also mean that two or more elements indirectly contact each other, but yet still cooperate or interact with each other, and may mean that one or more other elements are coupled or connected between the elements that are said to be coupled with each other. The term “directly coupled” may mean that two or more elements are in direct contact.

Various operations may be described as multiple discrete operations in turn, in a manner that is most helpful in understanding the claimed subject matter. However, the order of description should not be construed as to imply that these operations are necessarily order dependent.

As used herein, the term “module” may refer to, be part of, or include an application specific integrated circuit (ASIC), a field programmable gate array (FPGA), an electronic circuit, a processor (shared, dedicated, or group) and/or memory (shared, dedicated, or group) that execute one or more software or firmware programs, a combinational logic circuit, and/or other suitable components that provide the described functionality.

Various figures herein may depict one or more layers of one or more package assemblies. The layers depicted herein are depicted as examples of relative positions of the layers of the different package assemblies. The layers are depicted for the purposes of explanation, and are not drawn to scale. Therefore, comparative sizes of layers should not be assumed from the Figures, and sizes, thicknesses, or dimensions may be assumed for some embodiments only where specifically indicated or discussed.

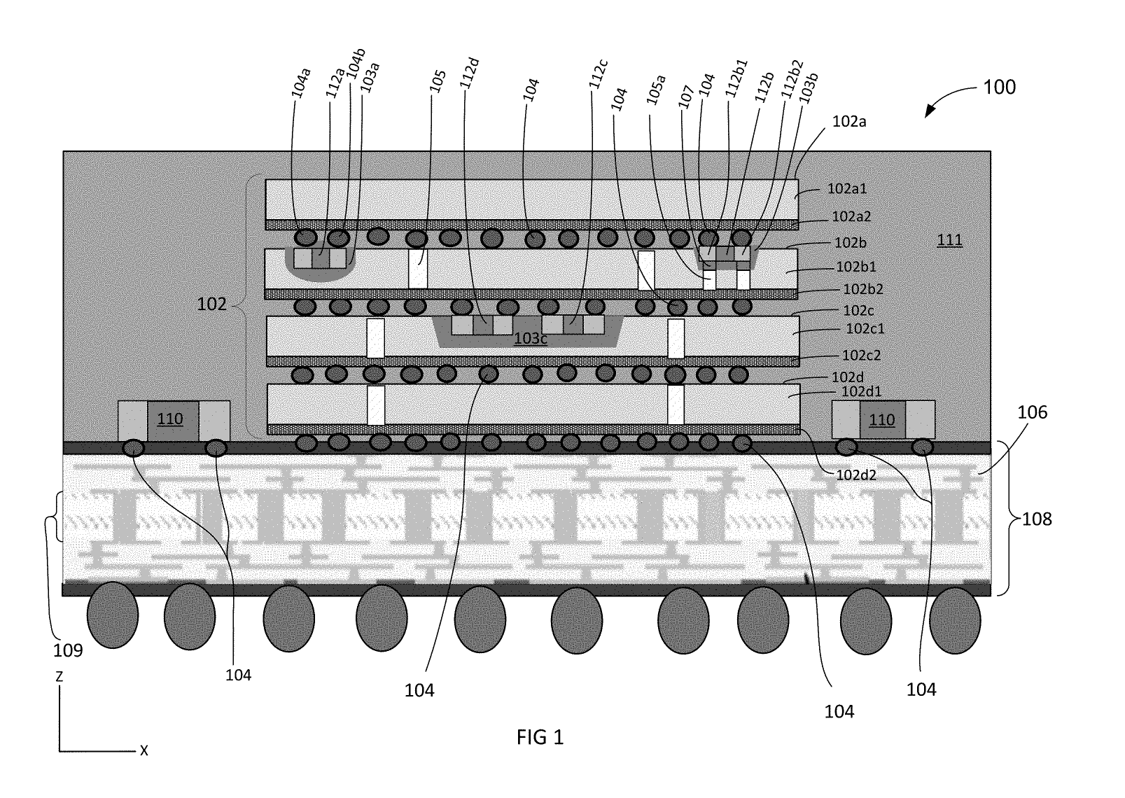

FIG. 1 illustrates an example of a vertically stacked die package assembly where the dies include one or more recesses, in accordance with embodiments. Diagram 100 may show a semiconductor package that includes stacked dies 102 that include individual dies 102a-102d. In embodiments, the individual dies 102a-102d may provide various functions, for example, a central processing unit (CPU), platform controller hub (PCH), dynamic random access (DRAM) memory, graphics processing unit (GPU), field programmable gate array (FPGA), or some other suitable function. In embodiments, one or more of the individual dies 102a-102d may have a silicon backside surface 102a1-102d1, which may be opposite of a silicon front side surface 102a2-102d2, which may include and/or be adjacent to or otherwise referred to as an active region of the die. In embodiments, this active region may include a transistor layer. In embodiments, the silicon backside surface 102a1-102d1 may include one or more active regions.

The individual dies 102a-102d may be electrically coupled to each other or to a package substrate 108 through solder bumps 104. In embodiments, the solder bumps 104 may be controlled collapsed chip connection (C4) bumps, or may be micro-bumps. In embodiments, the bottom die 102d may be connected to a redistribution layer (RDL) 106 that may be within the substrate 108. In embodiments, the substrate 108 may include a core layer 109 to, for example, provide mechanical support to stacked dies 102. In other embodiments, the substrate 108 may be without core layer 109 (e.g. a coreless package substrate) to further reduce the overall thickness of the package assembly. In embodiments, the RDL 106 may be directly formed on the active layer of the bottom die 102d and/or mold layer 111 without solder bumps 104, for example through bump-less build-up or wafer level packaging process.

In embodiments, DSCs 110 may be connected to the RDL 106 and/or substrate 108, for example through one or more solder connections such as solder bumps 104, that may provide power to the stacked dies 102. In embodiments, the stacked dies 102 may be electrically coupled to one another via bumps 104 and through silicon vias (TSVs) 105 that may serve as vertical interconnects.

In embodiments, one or more decoupling capacitors 112a-112d may be placed within silicon recesses 103a-103c, so that at least part of the decoupling capacitors 112a-112d may be placed within one or more recesses 103a-103c within a silicon backside surface, such as silicon backside surfaces 102b1, 102c1. In embodiments, the recesses (not shown) may be in the active surfaces 102b2-102d2.

In embodiments, a decoupling capacitor 112a-112d may include a multi-layer ceramic capacitor, a silicon capacitor, or other suitable capacitor. In embodiments, a decoupling capacitor 112a-112d may have an x-dimension ranging from 400 micrometers (μm) to 1000 μm, a y-dimension ranging from 200 μm to 500 μm, and/or a z-height ranging from 50 μm to 250 μm. In embodiments, a decoupling capacitor 112a-112d may be electrically coupled to at least one silicon die, for example, 102a, via solder connection such as solder bump 104. In embodiments, a depth of the recess 103a-103c may be determined based upon the dimensions of the decoupling capacitor 112a-112d that may partially extend into the recess 103a-103c.

One non-limiting example of such embodiments may include decoupling capacitor 112a that is attached via solder bumps 104a, 104b to the silicon active surface 102a2 of die 102. The decoupling capacitor 112a may partially reside within the recess 103a within die 102b. This may be referred to as a stacked-die capacitor. Note that this may be a similar structure as shown for decoupling capacitors 112c, 112d, where these capacitors are located next to each other.

In other embodiments, a decoupling capacitor 112b may be shared across two silicon dies 102a, 102b, for example, for common power rail applications. These embodiments may be referred to as an inter-die capacitor. In a non-limiting example, the decoupling capacitor 112b may reside within the recess 103b within die 102b. The decoupling capacitor 112b may then be electrically coupled to the active layer of the first die 102a2 through the solder bumps 104, and electrically coupled to the active layer of the second die 102b2 through solder connection 107 to a TSV 105a. In embodiments, the position of the power rail, power network and/or power loading of silicon dies 102a, 102b may be aligned with the decoupling capacitor 112b in a z-direction. In other embodiments, the position of the power rail, power network and/or power loading of silicon dies 102a, 102b may be offset from each other, from the decoupling capacitor 112b, or both.

In embodiments, a first terminal of a decoupling capacitor 112b1 may be electrically coupled to a first reference voltage source, for example, Vss or a ground reference voltage source of electrically coupled dies 102a, 102b. In embodiments, a second terminal of a decoupling capacitor 112b2 may be electrically coupled to a second reference voltage source that may be an opposite polarity as compared to the first reference voltage, for example, Vcc or power reference voltage source of electrically coupled dies 102a, 102b. In embodiments, this electrical coupling may occur respectively through various associated interconnect structures.

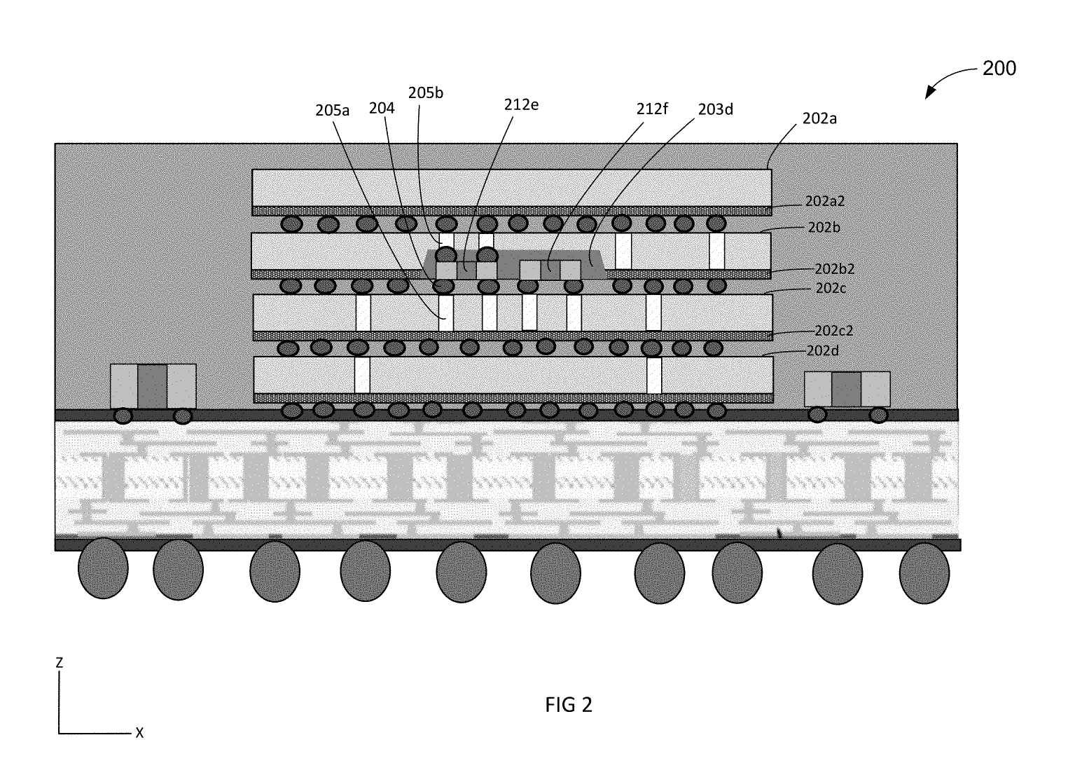

FIG. 2 illustrates an example of a vertically stacked die package assembly where the dies include one or more recesses with through silicon vias (TSV) connected to other dies, in accordance with embodiments. Diagram 200 illustrates embodiments of recesses, such as recess 203d, which may be similar to recess 103a-103c of FIG. 1, but may differ in certain respects. In embodiments, recess 203d may be etched into a silicon active surface 202b2, which may be similar to silicon active surface 102b2 of FIG. 1, of die 202b, which may be similar to die 102b. In embodiments, portions of one or more decoupling capacitors 212e, 212f may be included within recess 203d. In embodiments, the decoupling capacitor 212e may be connected to an active side 202c2 of die 202c using a TSV 205a, which may be similar to TSV 105 of FIG. 1, connected by a solder ball 204, which may be similar to solder ball 104 of FIG. 1 and may be referred to herein as solder bumps. The decoupling capacitor 212e may also be connected to an active side 202a2, which may be similar to active side 102a2 of FIG. 1, of die 202a using a TSV 205b. In similar embodiments, a single decoupling capacitor 212e may be referred to as an inter-die capacitor, and may service multiple layers of stacked dies 202a-202c.

Note that in these embodiments, the silicon recess 203d may be implemented within an active silicon device that may include a transceiver and/or data processing capabilities. In contrast, the silicon recess 103b of FIG. 1 may be implemented purely within a silicon portion, which may be referred to as passive silicon or a silicon bridge for interconnection purposes, of the die 102b. Returning to FIG. 2, embodiments may include a plurality of decoupling capacitors disposed within one or more recesses on a silicon front-side surface of a die 202a-202d and may represent embodiments of implementations of inter-die capacitors for wafer level packaging technology.

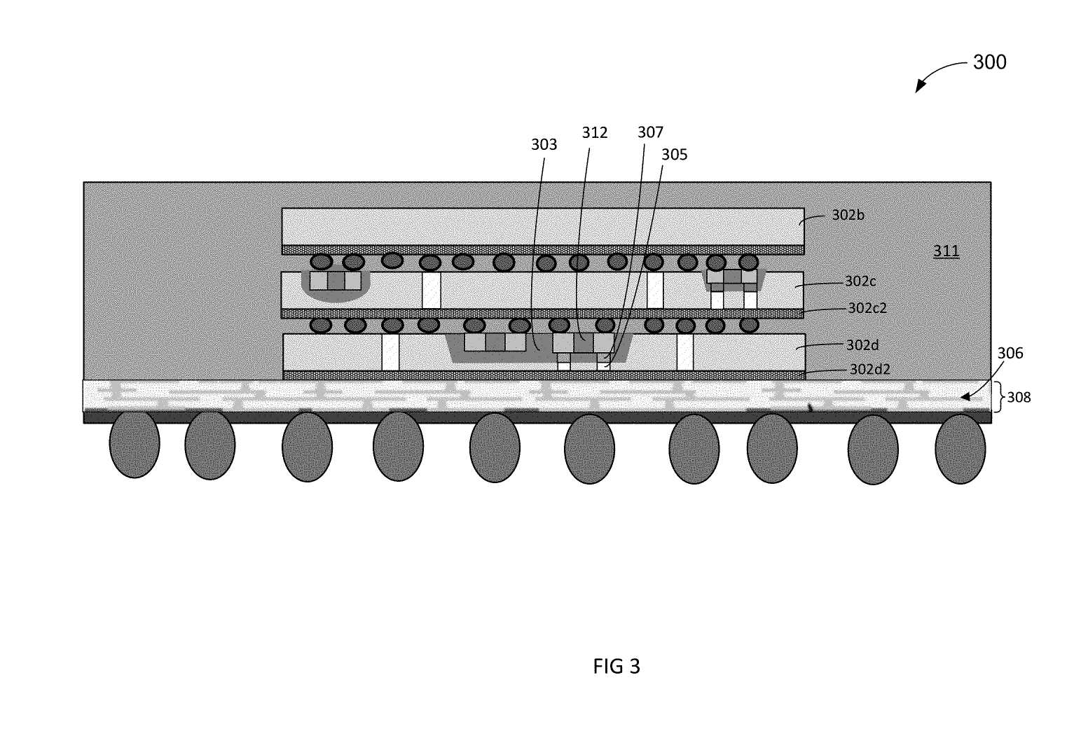

FIG. 3 illustrates an example of a vertically stacked die package assembly where the dies include one or more recesses with through silicon vias (TSV) connected to a substrate layer, in accordance with embodiments. Diagram 300 shows stacked dies 302b-302d, which may be similar to stacked dies 102b-102d of FIG. 1, with an active layer 302d2, which may be similar to active layer 102d2 of FIG. 1. Active layer 302d2 may be coupled directly to an RDL layer 306, which may be similar to RDL layer 106 of FIG. 1. In these embodiments, no solder balls or bumps, such as bumps 104 of FIG. 1, may be used to couple the RDL layer 306 and the active layer 302d2. In embodiments, a package consisting of dies 302b-302d may be coupled to the substrate 308, which may be similar to substrate 108 of FIG. 1, using a fan-out process or wafer level packaging through semi-additive processes such as dielectric lamination, etching, photolithography, electroplating, or other suitable process.

In embodiments, recess 303, which may be similar to recess 103c of FIG. 1, may include a decoupling capacitor 312, which may be similar to the decoupling capacitor 212f of FIG. 2, that is coupled to the active side 302c2 of die 302c. The decoupling capacitor 312 may be connected through solder 307, which may be similar to solder 107 of FIG. 1, and through a short TSV 305, which may be similar to TSV 105 of FIG. 1, to form an electrical connection with the active side 302d2 and RDL 306.

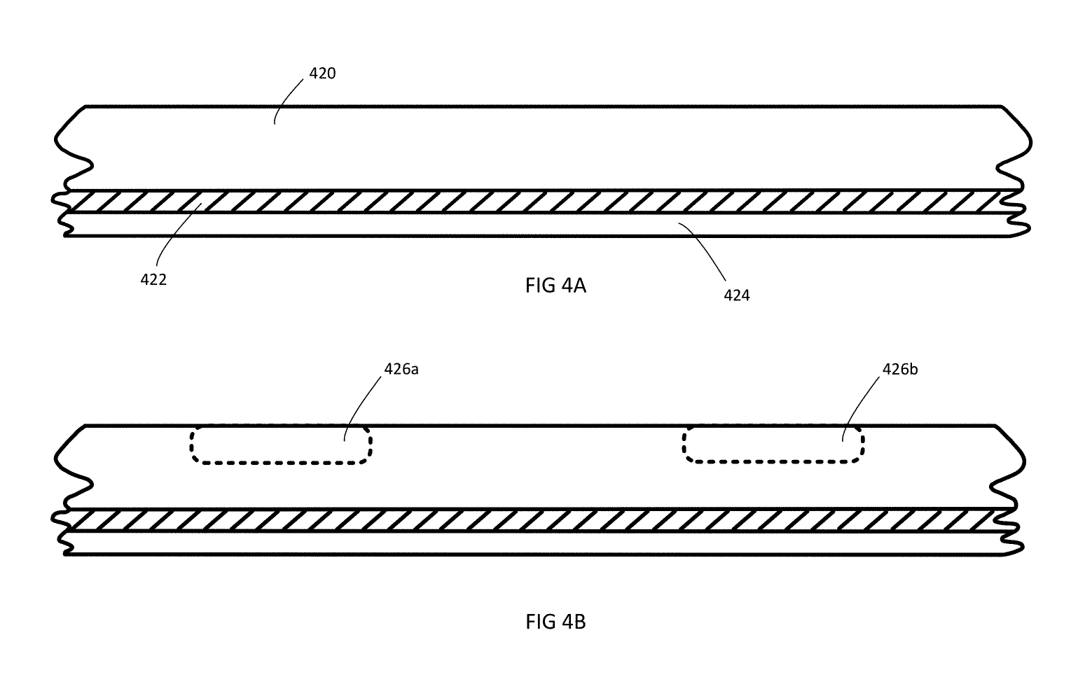

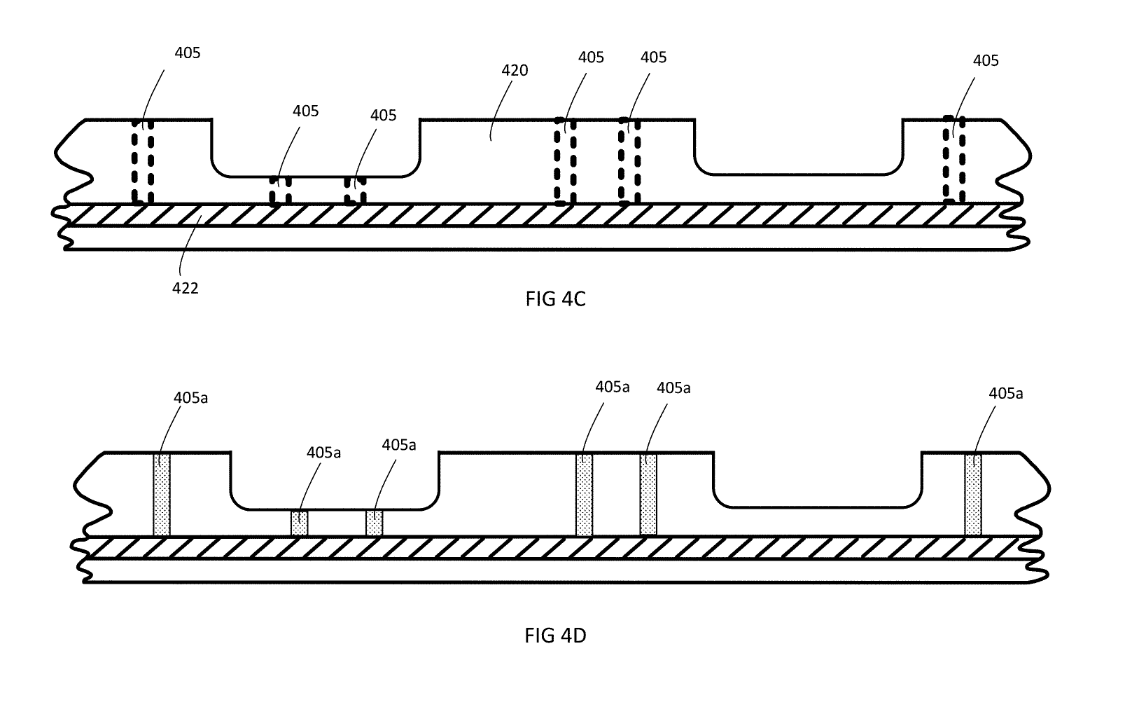

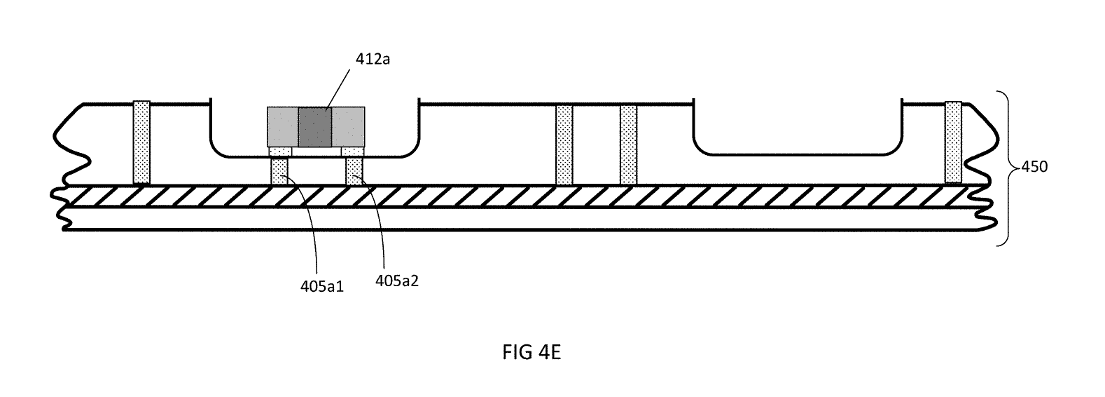

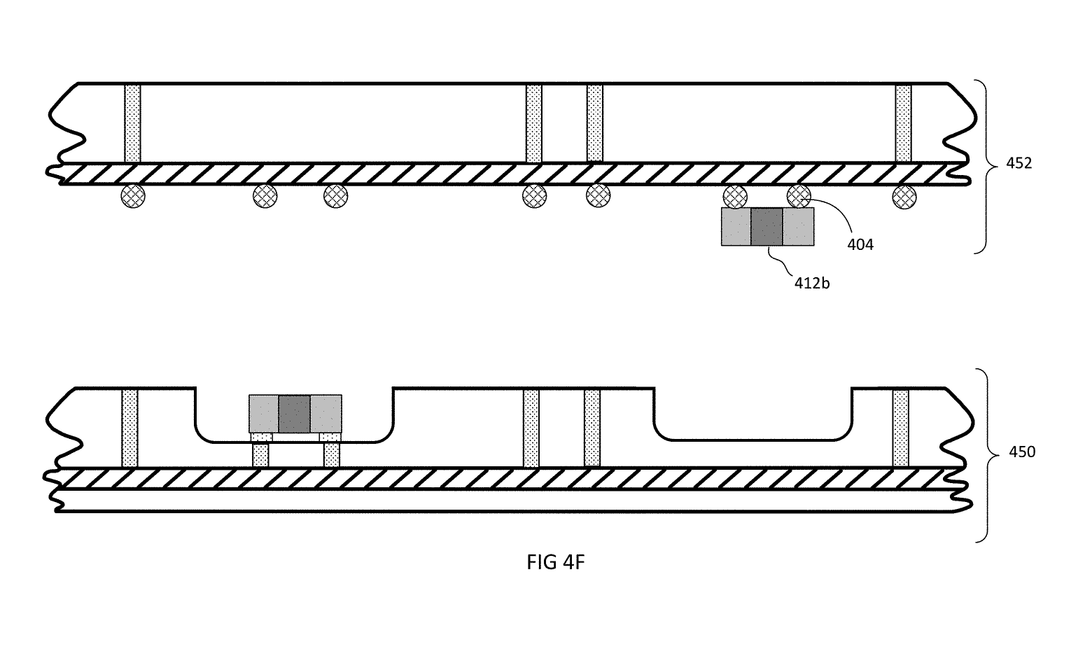

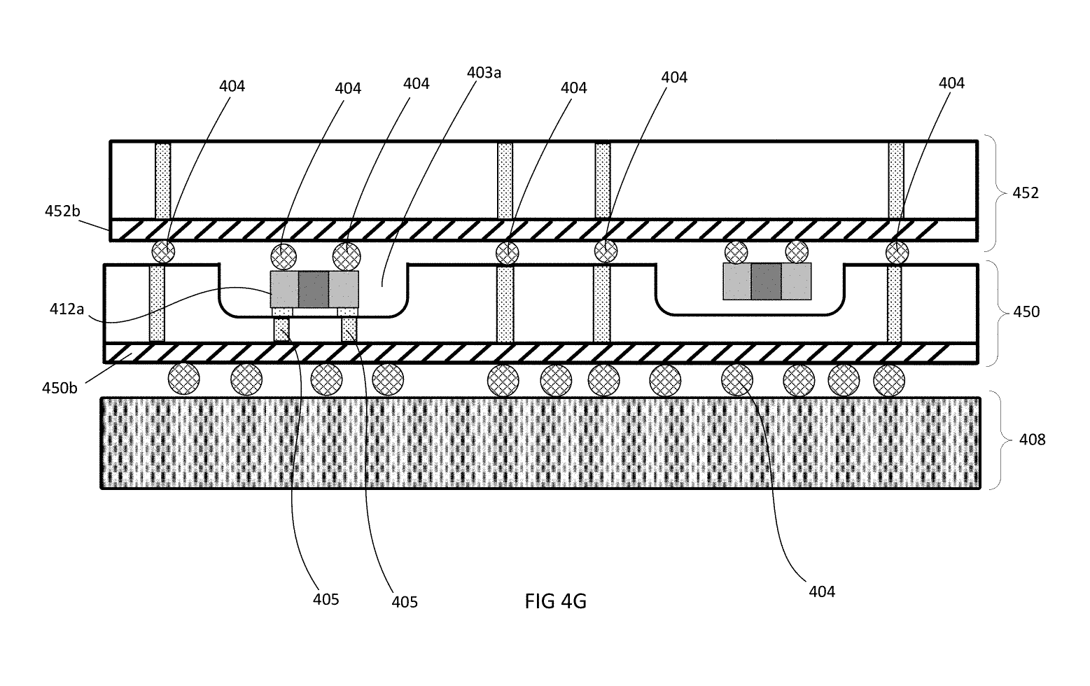

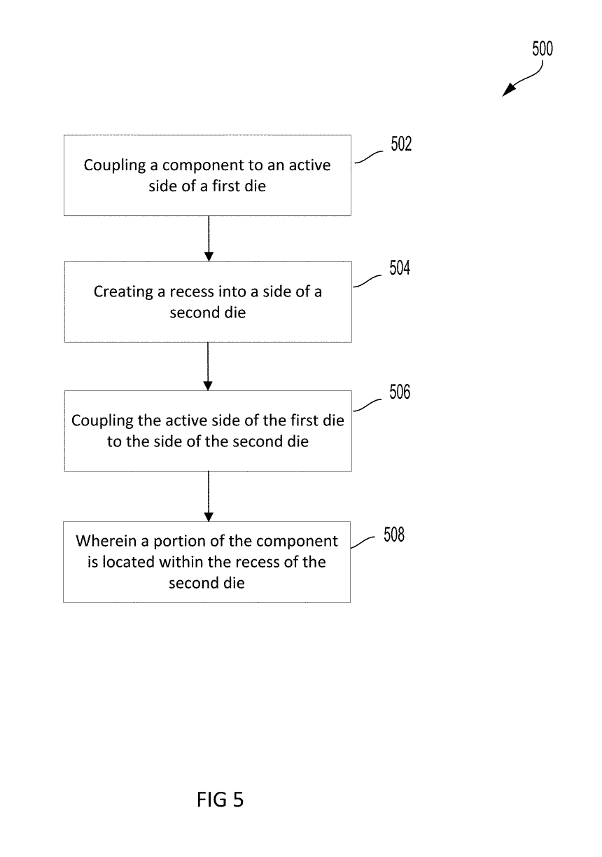

FIGS. 4A-4G illustrate an example of a vertically stacked die package assembly process where the dies include one or more recesses at various stages of a manufacturing process, in accordance with embodiments. Specifically, FIGS. 4A-4G shows a package assembly embodiment that includes various stages of a process flow incorporating the creation of recesses within one or more dies, insertion of passive components such as decoupling capacitors within the recesses, and then coupling the decoupling capacitors with various active layers of the one or more dies or of an RDL of a substrate. These various stages may be used to assemble a stacked die package with inter-die capacitors. In embodiments, the process order may vary in order to, for example, optimize assembly yield and/or throughput time.

FIG. 4A shows a wafer fabrication 420 that may include bulk silicon, which may be similar to silicon 102a1 of FIG. 1, or some other suitable substance. In embodiments, an active or passive layer 422, which may be similar to layer 102a2 of FIG. 1, may be applied to a surface of bulk silicon 420. In embodiments, an active layer 422 may include features that transmit signals or facilitate signal transmission. In embodiments, a passive layer 422 may include components that do not transmit, for example, capacitors or other passive components. In embodiments, a carrier 424 may be applied to the active or passive layer 422. In embodiments, the carrier may be a silicon substrate, or a metal plate such as an aluminum plate. In embodiments, an adhesive layer, for example Mylar® tape or polyimide adhesive may be attached to the carrier to provide mechanical protection to the active or passive layer 422.

FIG. 4B shows a bulk wafer etching process to etch two recesses 426a, 426b, which may be similar to recess 103a of FIG. 1, into a top surface of the bulk silicon 420. In embodiments, the recesses may be of different dimensions to accommodate different sizes of decoupling capacitors or other passive components. In embodiments, the wafer etching process may include plasma etch, mechanical etching, laser drilling, or some other suitable process to create the recesses 426a, 426b.

FIG. 4C shows TSVs 405 drilled through the bulk silicon 420 to the active or passive layer 422. In embodiments, the TSVs 405 may be created through plasma etch or laser drilling.

FIG. 4D shows TSVs 405 that have been filled 405a to provide electrical connection to the active or passive layer 422. In embodiments, the filled TSVs 405a may include filling from an electroless or electrolytic plating process, a sputtering process or other suitable technique.

FIG. 4E shows a decoupling capacitor 412a, which in embodiments may be some other passive component, that may be coupled with two filled TSVs 405a1, 405a2. embodiments, the coupling may be accomplished using an attach process. In embodiments, the attach process may include surface mounting and/or solder reflow process. The result may be shown as die 450.

FIG. 4F shows a second die 452 that may be similar to die 102a from FIG. 1 that has a decoupling capacitor 412b, which may be similar to decoupling capacitor 412a of FIG. 4E, attached via solder bumps 404, which may be similar to solder bumps 104 of FIG. 1. As shown, the second die 452 may be positioned above the die 450, which may be similar to die 450 of FIG. 4E, in preparation for coupling of the two dies 452, 450.

FIG. 4G shows the second die 452 coupled with the first die 450 using solder balls 404. Recess 403a shows a decoupling capacitor 412a that is electrically coupled both with active layer 452b using solder balls 404 and coupled with active layer 450b using TSVs 405. In addition, the coupled dies 452, 450 are coupled to the substrate 408 using solder balls 404. In embodiments, this connection to the substrate may have been through a redistribution layer (RDL) (not shown) on the substrate 408.

FIG. 5 illustrates an example flow diagram showing a process 500 for manufacturing a stacked die package where the dies include one or more recesses that include passive components, in accordance with embodiments. In embodiments, process 500 may be used to manufacture a package assembly as depicted in diagram 100, 200, 300, and/or FIG. 4G.

At block 502, the process may include coupling a component to an active side of a first die. In embodiments, the first die may be die 102a of FIG. 1, with an active side 102a2. The component may be component 112a, which may be a decoupling capacitor or some other passive component that may be connected to the active side 102a2 using solder ball 104a, 104b. In embodiments, the solder balls 104a, 104b may be referred to as micro-bumps.

At block 504, the process may include creating a recess into a side of a second die. In embodiments, the second die may be die 102b and the recess may be recess 103a of FIG. 1. In embodiments, as described herein, the recess may be created in the silicon portion 102b1 of the die 102b using a wafer etching process that may include plasma etch, mechanical etching, laser drilling, or some other suitable process to create the recess. In embodiments, multiple recesses may be created. In embodiments, the recess may be made in the silicon side of the die, such as silicon side 102c1 of FIG. 1, or the recess may be made on the active side of the die, such as side 202b2 of FIG. 2.

At block 506, the process may include coupling an active side of the first die to the side of the second die. In embodiments, coupling may include physically attaching a first die such as first die 102a and second die 102b of FIG. 1 using solder balls 104 which may also be referred to as solder bumps. In embodiments, the coupling may include solder balls 104 that electrically couple an active surface of the first die 102a2 to an active surface of the second die 102b2 with a TSV 105. In embodiments, other electrical couplings between a first die and the second die may result in various embodiments involving one or more decoupling capacitors 112a-112d, for example.

At block 508, the process may include a portion of the component located within the recess of the second die. In embodiments, this may be seen throughout FIGS. 1-3 and FIGS. 4E-4F. In embodiments, decoupling capacitor 112a may be located within the recess 103a. In embodiments, as described above, the recess 103a may have dimensions based upon the physical dimensions of the decoupling capacitor 112a, or of some other passive component that may be located partially within the recess 103a. In embodiments as shown herein, the decoupling capacitor 112b, or other passive component, may be electrically coupled to the active layer of the second die using solder balls 104, solder 107, and/or TSVs 105a as shown in FIG.

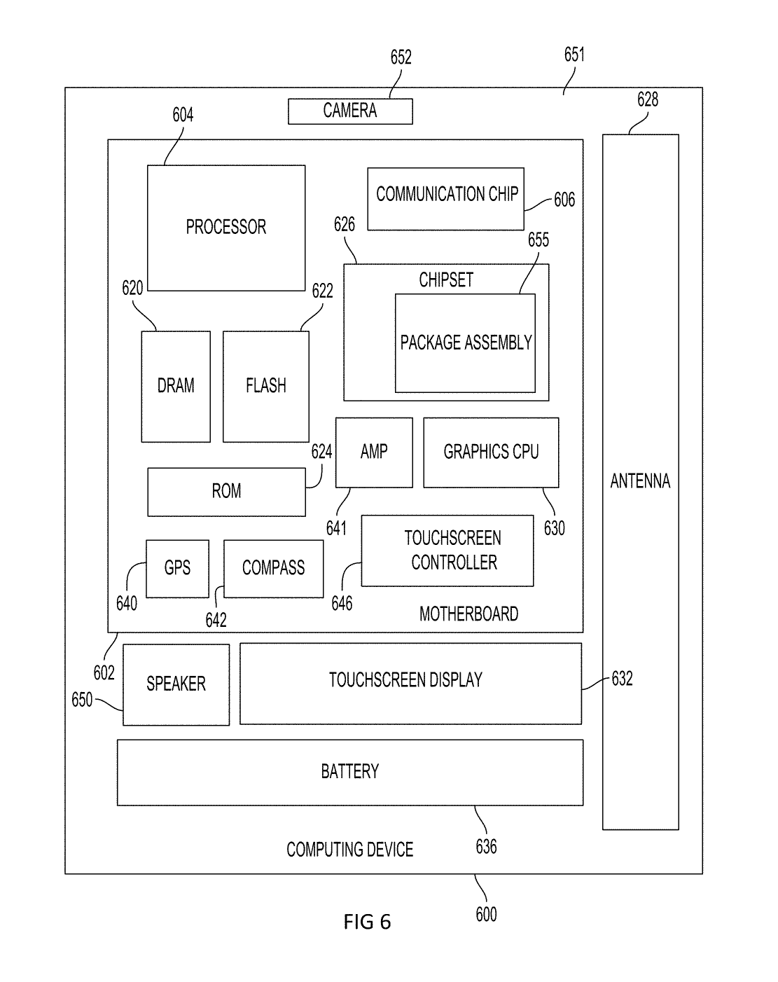

FIG. 6 schematically illustrates a computing device, in accordance with embodiments. Embodiments of the present disclosure may be implemented into a system using any suitable hardware and/or software to configure as desired. FIG. 6 schematically illustrates a computing device 600 in accordance with one embodiment. The computing device 600 may house a board such as motherboard 602 (i.e., housing 651). The motherboard 602 may include a number of components, including but not limited to a processor 604 and at least one communication chip 606. The processor 604 may be physically and electrically coupled to the motherboard 602. In some implementations, the at least one communication chip 606 may also be physically and electrically coupled to the motherboard 602. In embodiments, the at least one communication chip 606 may be or may include stacked dies 102 of FIG. 1, stacked dies 202a-202d of FIG. 2, stacked dies 302b-302d of FIG. 3, stacked dies as shown in FIG. 4G, or other similar stacked dies having components within recesses within the stacked dies.

Depending on its applications, computing device 600 may include other components that may or may not be physically and electrically coupled to the motherboard 602. These other components may include, but are not limited to, volatile memory (e.g., DRAM) 620, non-volatile memory (e.g., ROM) 624, flash memory 622, a graphics processor 630, a digital signal processor (not shown), a crypto processor (not shown), a chipset 626, an antenna 628, a display (not shown), a touchscreen display 632, a touchscreen controller 646, a battery 636, an audio codec (not shown), a video codec (not shown), a power amplifier 641, a global positioning system (GPS) device 640, a compass 642, an accelerometer (not shown), a gyroscope (not shown), a speaker 650, a camera 652, and a mass storage device (such as hard disk drive, compact disk (CD), digital versatile disk (DVD), and so forth) (not shown). Further components, not shown in FIG. 6, may include a microphone, a filter, an oscillator, a pressure sensor, or an RFID chip. In embodiments, one or more of the package assembly components 655 may be a package assembly such as a package as shown in diagram 100 of FIG. 2, diagram 200 of FIG. 2, diagram 300 of FIG. 3, a package as shown in FIG. 4G, or other similar packages having components within recesses in one or more stacked dies of the packages.

The communication chip 606 may enable wireless communications for the transfer of data to and from the computing device 600. The term “wireless” and its derivatives may be used to describe circuits, devices, systems, processes, techniques, communications channels, etc., that may communicate data through the use of modulated electromagnetic radiation through a non-solid medium. The term does not imply that the associated devices do not contain any wires, although in some embodiments they might not. The communication chip 606 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra-mobile broadband (UMB) project (also referred to as “3GPP2”), etc.). IEEE 802.16 compatible broadband wireless access (BWA) networks are generally referred to as WiMAX networks, an acronym that stands for Worldwide Interoperability for Microwave Access, which is a certification mark for products that pass conformity and interoperability tests for the IEEE 802.16 standards. The communication chip 606 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication chip 606 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication chip 606 may operate in accordance with Code Division Multiple Access (CDMA), Time Division Multiple Access (TDMA), Digital Enhanced Cordless Telecommunications (DECT), Evolution-Data Optimized (EV-DO), derivatives thereof, as well as any other wireless protocols that are designated as 3G, 4G, 5G, and beyond. The communication chip 606 may operate in accordance with other wireless protocols in other embodiments.

The computing device 600 may include a plurality of communication chips 606. For instance, a first communication chip 606 may be dedicated to shorter range wireless communications such as Wi-Fi and Bluetooth and a second communication chip 606 may be dedicated to longer range wireless communications such as GPS, EDGE, GPRS, CDMA, WiMAX, LTE, Ev-DO, laser communications, photonics communications and others.

The processor 604 of the computing device 600 may include a die in a package assembly such as, for example, one of package assemblies as shown in diagram 100 of FIG. 1, diagram 200 of FIG. 2, diagram 300 of FIG. 3, and/or a package assembly as shown in FIG. 4G, described herein. The term “processor” may refer to any device or portion of a device that processes electronic data from registers and/or memory to transform that electronic data into other electronic data that may be stored in registers and/or memory.

In various implementations, the computing device 600 may be a laptop, a netbook, a notebook, an Ultrabook™, a smartphone, a tablet, a personal digital assistant (PDA), an ultra-mobile PC, a mobile phone, a desktop computer, a server, a printer, a scanner, a monitor, a set-top box, an entertainment control unit, a digital camera, a portable music player, or a digital video recorder. In further implementations, the computing device 600 may be any other electronic device that processes data, for example, an all-in-one device such as an all-in-one fax or printing device.

### EXAMPLES

Example 1 may be a package comprising: a first die with a first side and a second side opposite the first side; a second die with a first side coupled to the second side of the first die; a recess in the first side of the second die; wherein a portion of a passive component is located within the recess of the first side of the second die; and wherein the passive component is coupled with the first die, the second die, or both.

Example 2 may include the package of example 1, wherein the first die or the second die is coupled with a substrate.

Example 3 may include the package of example 1, wherein the passive component is a plurality of passive components.

Example 4 may include the package of example 1, wherein a set of dimensions of the recess is based on a set of dimensions of the passive component.

Example 5 may include the package of example 1, wherein the passive component is a capacitor.

Example 6 may include the package of example 1, wherein the passive component is coupled with an active layer of the first die.

Example 7 may include the package of example 1, wherein the passive component is coupled with an active layer of the second die.

Example 8 may include the package of example 7, wherein a through silicon via (TSV) couples the passive component with the active layer of the second die.

Example 9 may include the package of any examples 6-8, wherein the active layer is a redistribution layer (RDL).

Example 10 may include the package of example 1, wherein the recess is within a silicon portion of the second die.

Example 11 may include the package of example 1, wherein the first die and the second die are coupled via a solder connection.

Example 12 may include the package of example 11, wherein the solder connection is a set of micro-bumps or controlled collapsed chip connection (C4) bumps.

Example 13 may include the package of example 1, wherein the component is a decoupling capacitor to provide power to the first die, the second die, or both.

Example 14 may include the package of example 13, wherein the decoupling capacitor is a multi-layer ceramic capacitor or a silicon capacitor.

Example 15 may include the package of example 13, wherein the decoupling capacitor has a first length parallel to the first side of the second surface from 400 micrometers (μm) to 1000 μm, has a second length parallel to the first side of the second surface and perpendicular to the first length of 200 μm to 500 μm, and a third length perpendicular to the first length and the second length from 50 μm to 250 μm.

Example 16 may include the package of example 1, wherein a first terminal of the passive component is coupled to a first reference voltage source and a second terminal of the passive component is coupled to a second reference voltage source.

Example 17 may include the package of example 16, wherein the first reference voltage source is a ground reference voltage source (Vss) and the second reference voltage source is a power reference voltage source (Vcc).

Example 18 may include the package of example 16, wherein the first reference voltage source and the second reference voltage source are opposite polarities.

Example 19 may be a method for creating a package, comprising: coupling a component to an active side of a first die; creating a recess into a side of a second die; coupling the active side of the first die to the side of the second die; wherein the first die and the second die are coupled; and wherein a portion of the component is located within the recess of the second die.

Example 21 may include the method of example 20, further comprising coupling the component to an active layer of the second die.

Example 22 may include the method of example 21, wherein coupling the component to an active layer of the second die further includes coupling the component to an active layer of the second die using a through-silicon via (TSV).

Example 23 may include the method of example 21, wherein the component is a passive component.

Example 24 may be a system comprising: a package substrate; a first die with a first side and a second side opposite the first side; a second die with a first side coupled to the second side of the first die; a recess in the first side of the second die; wherein a portion of a passive component is located within the recess of the first side of the second die; wherein the passive component is coupled with the first die, the second die, or both; and wherein the first die or the second die is coupled with the substrate.

Example 25 may include the system of example 24, wherein the passive component is a plurality of passive components.

Example 26 may include the system of example 24, wherein a set of dimensions of the recess is based on a set of dimensions of the passive component.

Example 27 may include the system of example 24, wherein the passive component is a capacitor.

Example 28 may include the system of example 24, wherein the passive component is coupled with an active layer of the first die.

Example 29 may include the system of example 24, wherein the passive component is coupled with an active layer of the second die.

Example 30 may include the system of example 29, wherein a through silicon via (TSV) couples the passive component with the active layer of the second die.

Example 31 may include the system of any examples 29-30, wherein the active layer is a redistribution layer (RDL).

Example 32 may include the system of example 24, wherein the recess is within a silicon portion of the second die.

Example 33 may include the system of example 24, wherein the first die and the second die are coupled via a solder connection.

Example 34 may include the system of example 33, wherein the solder connection is a set of micro-bumps or controlled collapsed chip connection (C4) bumps.

Example 35 may include the system of example 24, wherein the component is a decoupling capacitor to provide power to the first die, the second die, or both.

Example 36 may include the system of example 35, wherein the decoupling capacitor is a multi-layer ceramic capacitor or a silicon capacitor.

Example 37 may include the system of example 35, wherein the decoupling capacitor has a first length parallel to the first side of the second surface from 400 micrometers (μm) to 1000 μm, has a second length parallel to the first side of the second surface and perpendicular to the first length of 200 μm to 500 μm, and a third length perpendicular to the first length and the second length from 50 μm to 250 μm.

Example 38 may include the system of example 24, wherein a first terminal of the passive component is coupled to a first reference voltage source and a second terminal of the passive component is coupled to a second reference voltage source.

Example 39 may include the system of example 38, wherein the first reference voltage source is a ground reference voltage source (Vss) and the second reference voltage source is a power reference voltage source (Vcc).

Example 40 may include the system of example 38, wherein the first reference voltage source and the second reference voltage source are opposite polarities.

Example 41 may be package, comprising: means for coupling a component to an active side of a first die; means for creating a recess into a side of a second die; means for coupling the active side of the first die to the side of the second die; means for wherein the first die and the second die are coupled; and means for wherein a portion of the component is located within the recess of the second die.

Example 42 may include the package of example 41, further comprising means for coupling the component to an active layer of the second die.

Example 43 may include the package of example 42, wherein means for coupling the component to an active layer of the second die further includes means for coupling the component to an active layer of the second die using a through-silicon via (TSV).

Example 44 may include the package of example 42, wherein the component is a passive component.

Various embodiments may include any suitable combination of the above-described embodiments including alternative (or) embodiments of embodiments that are described in conjunctive form (and) above (e.g., the “and” may be “and/or”). Furthermore, some embodiments may include one or more articles of manufacture (e.g., non-transitory computer-readable media) having instructions, stored thereon, that when executed result in actions of any of the above-described embodiments. Moreover, some embodiments may include apparatuses or systems having any suitable means for carrying out the various operations of the above-described embodiments.

The above description of illustrated embodiments, including what is described in the Abstract, is not intended to be exhaustive or to limit embodiments to the precise forms disclosed. While specific embodiments are described herein for illustrative purposes, various equivalent modifications are possible within the scope of the embodiments, as those skilled in the relevant art will recognize.

These modifications may be made to the embodiments in light of the above detailed description. The terms used in the following claims should not be construed to limit the embodiments to the specific implementations disclosed in the specification and the claims. Rather, the scope of the invention is to be determined entirely by the following claims, which are to be construed in accordance with established doctrines of claim interpretation.

1-25. (canceled)

26. A package comprising:
a first die with a first side and a second side opposite the first side;
a second die with a first side coupled to the second side of the first die;
a recess in the first side of the second die;
wherein a portion of a passive component is located within the recess of the first side of the second die; and
wherein the passive component is coupled with the first die, the second die, or both.

27. The package of claim 26, wherein the first die or the second die is coupled with a substrate.

28. The package of claim 26, wherein the passive component is a plurality of passive components.

29. The package of claim 26, wherein a set of dimensions of the recess is based on a set of dimensions of the passive component.

30. The package of claim 26, wherein the passive component is a capacitor.

31. The package of claim 26, wherein the passive component is coupled with an active layer of the first die.

32. The package of claim 26, wherein the passive component is coupled with an active layer of the second die.

33. The package of claim 32, wherein a through silicon via (TSV) couples the passive component with the active layer of the second die.

34. The package of claim 31, wherein the active layer is a redistribution layer (RDL).

35. The package of claim 26, wherein the recess is within a silicon portion of the second die.

36. The package of claim 26, wherein the first die and the second die are coupled via a solder connection.

37. The package of claim 36, wherein the solder connection is a set of micro-bumps or controlled collapsed chip connection (C4) bumps.

38. The package of claim 26, wherein the component is a decoupling capacitor to provide power to the first die, the second die, or both.

39. The package of claim 38, wherein the decoupling capacitor is a multi-layer ceramic capacitor or a silicon capacitor.

40. A method for creating a package, comprising:
coupling a component to an active side of a first die;
creating a recess into a side of a second die;
coupling the active side of the first die to the side of the second die;
wherein the first die and the second die are coupled; and
wherein a portion of the component is located within the recess of the second die.

41. The method of claim 40, further comprising coupling the component to an active layer of the second die.

42. The method of claim 41, wherein coupling the component to an active layer of the second die further includes coupling the component to an active layer of the second die using a through-silicon via (TSV).

43. The method of claim 41, wherein the component is a passive component.

44. A system comprising:
a package substrate;
a first die with a first side and a second side opposite the first side;
a second die with a first side coupled to the second side of the first die;
a recess in the first side of the second die;
wherein a portion of a passive component is located within the recess of the first side of the second die;
wherein the passive component is coupled with the first die, the second die, or both; and
wherein the first die or the second die is coupled with the substrate.

45. The system of claim 44, wherein the passive component is a plurality of passive components.

46. The system of claim 44, wherein a set of dimensions of the recess is based on a set of dimensions of the passive component.

47. The system of claim 44, wherein the passive component is a capacitor.

48. The system of claim 44, wherein the passive component is coupled with an active layer of the first die.

49. The system of claim 44, wherein the passive component is coupled with an active layer of the second die.

50. The package of claim 49, wherein a through silicon via (TSV) couples the passive component with the active layer of the second die.
